(19) United States
(12) Patent Application Publication
(10) Pub. No.: US 2025/0379550 A1
(43) Pub. Date: Dec. 11, 2025

(54) DECISION FEEDBACK EQUALIZER WITH VARIABLE GAIN AMPLIFIER

(71) Applicant: Micron Technology, Inc., Boise, ID (US)

(72) Inventors: Jinha Hwang, Boise, ID (US); Won Joo Yun, Boise, ID (US)

(21) Appl. No.: 19/063,995

(22) Filed: Feb. 26, 2025

Related U.S. Application Data
(60) Provisional application No. 63/658,622, filed on Jun. 11, 2024.

(51) Int. Cl. H03F 3/45; H04L 25/03

(52) U.S. Cl. CPC H03F 3/45183; H04L 25/03057

(57) ABSTRACT

A device is provided that includes a decision feedback equalizer (DFE) with a first summer circuit and a second summer circuit. The DFE also includes a first double tail latch circuit coupled to the first summer circuit and a feedback path disposed between latches of the first double tail latch circuit and coupled to the second summer circuit to provide a tap signal to the second summer circuit. The DFE further includes another double tail latch circuit coupled to the second summer circuit and a feedback path disposed between latches of the second double tail latch circuit and coupled to the first summer circuit to provide a tap signal to the first summer circuit.

### CROSS REFERENCE TO RELATED APPLICATIONS

This application is a Non-Provisional Application claiming priority to U.S. Provisional Patent Application No. 63/658,622, entitled “DECISION FEEDBACK EQUALIZER WITH VARIABLE GAIN AMPLIFIER”, filed Jun. 11, 2024, which is herein incorporated by reference.

### BACKGROUND

### Field of the Present Disclosure

Embodiments of the present disclosure relate generally to the field of input buffers and Decision Feedback Equalizers (DFEs) for memory devices. More specifically, embodiments of the present disclosure relate to reducing signal path delay for taps of the DFE.

### Description of Related Art

The operational rate of memory devices, including the data rate of a memory device, has been increasing over time. As a side effect of the increase in speed of a memory device, data errors due to distortion may increase. For example, inter-symbol interference between transmitted data whereby previously received data influences the currently received data may occur (e.g., previously received data affects and interferes with subsequently received data). One manner to correct for this interference is through the use of a decision feedback equalizer (DFE) circuit, which may be programmed to offset (i.e., undo or mitigate) the effect of the channel on the transmitted data.

To insure the proper functioning of the DFE circuit, reliable input signals should be available. Additionally, as rates of operation increase (e.g., as data speeds increase), the DFE should be able to correct for inter-symbol interference at a rate that at least matches the rate of incoming data.

Embodiments of the present disclosure may be directed to one or more of the problems set forth above.

### BRIEF DESCRIPTION OF DRAWINGS

Various aspects of this disclosure may better be understood upon reading the following detailed description and upon reference to the drawings in which:

FIG. 1 is a simplified block diagram illustrating certain features of a memory device, according to an embodiment of the present disclosure;

FIG. 2 is a block diagram illustrating a data transceiver of the I/O interface of FIG. 1, according to an embodiment of the present disclosure;

FIG. 3 illustrates a block diagram of an embodiment of the data transceiver of FIG. 2, according to an embodiment of the present disclosure;

FIG. 4 illustrates a high level diagram of a Decision Feedback Equalizer of the data transceiver of FIG. 2, according to an embodiment of the present disclosure;

FIG. 5 illustrates a block diagram of a first embodiment of the DFE of FIG. 4, according to an embodiment of the present disclosure;

FIG. 6 illustrates a block diagram of a second embodiment the DFE of FIG. 4, according to an embodiment of the present disclosure;

FIG. 7 illustrates a first embodiment of circuitry utilized in the second embodiment of the DFE of FIG. 6, according to an embodiment of the present disclosure;

FIG. 8 illustrates a second embodiment of circuitry utilized in the second embodiment of the DFE of FIG. 6, according to an embodiment of the present disclosure; and

FIG. 9 illustrates a third embodiment of circuitry utilized in the second embodiment of the DFE of FIG. 6, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Using a decision feedback equalizer (DFE) of a memory device to perform distortion correction techniques may be valuable, for example, to correctly compensate for distortions in the received data of the memory device. This insures that accurate values are being stored in the memory of the memory device. The DFE may use previous bit data to create corrective values to compensate for distortion resulting from previously received data bit(s). For example, the most recent previous bit may have more of a distortion effect on the current bit than a bit transmitted several data points before, causing the corrective values to be different between the two bits. With these levels to correct for, the DFE may operate to correct the distortion of the transmitted bit.

However, as operating speeds continue to increase, transmission paths of the DFE can become too slow to adequately transmit corrective signals to be applied to incoming data bits. Accordingly, different architectures that reduce signal transmission time are contemplated and are described herein. For example, one embodiment of a DFE that can operate with reduced looptime margin is discussed below as including a first summer circuit and a second summer circuit with a first double tail latch circuit coupled to the first summer circuit. A feedback path is provided from a node between latches of the first double tail latch circuit to the second summer circuit and provides a tap signal to the second summer circuit. Likewise, a second double tail latch circuit is present in the DFE as coupled to the second summer circuit. An additional feedback path is provided from a node between latches of the second double tail latch circuit to the first summer circuit to provide a tap signal to the first summer circuit. Utilizing this layout, selection circuitry (e.g., multiplexers) can be omitted from the DFE, thus removing the delays associated therewith.

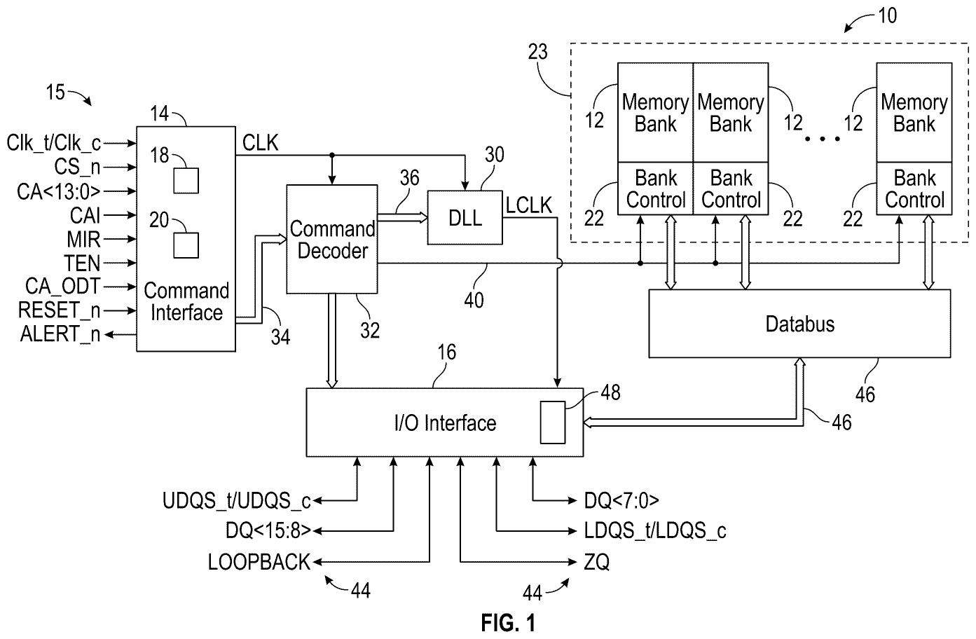

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous dynamic random access memory (DDR5 SDRAM or DDR5) device. Various features of DDR5 SDRAM allow for reduced power consumption, more bandwidth and more storage capacity compared to prior generations of DDR SDRAM. However, more generally, the memory device 10 may be a random access memory (RAM) device, a dynamic RAM (DRAM) device, a static RAM (SRAM) device (including a double data rate SRAM device), flash memory, and/or a phase change memory (PCM) device and/or other chalcogenide-based memory, such as self-selecting memories (SSM), a double data rate type four synchronous dynamic random access memory (DDR4 SDRAM) device, a low power double data rate type four synchronous dynamic random access memory (LPDDR4 SDRAM), a low power double data rate type five synchronous dynamic random access memory (LPDDR5 SDRAM) device, a data rate type six synchronous dynamic random access memory (DDR6 SDRAM or DDR6), or another type of device.

The memory device 10, may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 GB DDR5 SDRAM, the memory chip may include 32 memory banks 12, arranged into 8 bank groups, each bank group including 4 memory banks, for instance. Various other configurations, organization and sizes of the memory banks 12 on the memory device 10 may be utilized depending on the application and design of the overall system.

The memory device 10 may include a command interface 14 and an input/output (I/O) interface 16 configured to exchange (e.g., receive and transmit) signals with external devices. The command interface 14 is configured to provide a number of signals (e.g., signals 15) from an external device (not shown), such as a processor or controller (e.g., present in a host device coupled to the memory device 10). The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command address input circuit 20, for instance, to ensure proper handling of the signals 15. The command interface 14 may receive one or more clock signals from an external device. Generally, double data rate (DDR) memory utilizes a differential pair of system clock signals, referred to herein as the true clock signal (Clk_t) and the complementary clock signal (Clk_c). The positive clock edge for DDR refers to the point where the rising true clock signal Clk_t crosses the falling complementary clock signal Clk_c, while the negative clock edge indicates the transition of the falling true clock signal Clk_t and the rising of the complementary clock signal Clk_c. Commands (e.g., read command, write command, etc.) are typically entered on the positive edges of the clock signal and data is transmitted or received on both the positive and negative clock edges.

The clock input circuit 18 receives the true clock signal (Clk_t) and the complementary clock signal (Clk_c) and generates an internal clock signal CLK. The internal clock signal CLK is supplied to an internal clock generator 30, such as a delay locked loop (DLL) circuit. The internal clock generator 30 generates a phase controlled internal clock signal LCLK based on the received internal clock signal CLK. The phase controlled internal clock signal LCLK is supplied to the input/output (I/O) interface 16, for instance, and is used as a timing signal for determining an output timing of read data.

The internal clock signal CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For example, the command decoder 32 may provide command signals to the internal clock generator 30 over the bus 36 to coordinate generation of the phase controlled internal clock signal LCLK. The phase controlled internal clock signal LCLK may be used to clock data through the I/O interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes a bank control block 22 which provides decoding (e.g., row decoder and column decoder), as well as other features, such as timing control and data control, to facilitate the execution of commands to and from the memory banks 12. Collectively, the memory banks 12 and the bank control blocks 22 may be referred to as a memory array 23.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20 which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 16. More specifically, the data may be sent to or retrieved from the memory banks 12 over the data bus 46, which includes a plurality of bi-directional data buses. Data I/O signals, generally referred to as DQ signals, are generally transmitted and received in one or more bi-directional data busses. For certain memory devices, such as a DDR5 SDRAM memory device, the I/O signals may be divided into upper and lower bytes. For instance, for an x16 memory device, the I/O signals may be divided into upper and lower I/O signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the data strobe (DQS) signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

An impedance (ZQ) calibration signal may also be provided to the memory device 10 through the I/O interface 16. The ZQ calibration signal may be provided to a reference pin and used to tune output drivers and on die termination values (ODT) by adjusting pull-up and pull-down resistors of the memory device 10 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the I/O pins.

In addition, a loopback signal (LOOPBACK) may be provided to the memory device 10 through the I/O interface 16. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the I/O interface 16.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into a memory system incorporating the memory device 10. Accordingly, it should be understood that the block diagram of FIG. 1 is only provided to highlight certain functional features of the memory device 10 to aid in the subsequent detailed description.

In some embodiments, the memory device 10 may be disposed in (physically integrated into or otherwise connected to) a host device or otherwise coupled to a host device. The host device may include any one of a desktop computer, laptop computer, pager, cellular phone, personal organizer, portable audio player, control circuit, camera, etc. The host device may also be a network node, such as a router, a server, or a client (e.g., one of the previously-described types of computers). The host device may be some other sort of electronic device, such as a copier, a scanner, a printer, a game console, a television, a set-top video distribution or recording system, a cable box, a personal digital media player, a factory automation system, an automotive computer system, or a medical device. (The terms used to describe these various examples of systems, like many of the other terms used herein, may share some referents and, as such, should not be construed narrowly in virtue of the other items listed.)

The host device may, thus, be a processor-based device, which may include a processor, such as a microprocessor, that controls the processing of system functions and requests in the host. Further, any host processor may comprise a plurality of processors that share system control. The host processor may be coupled directly or indirectly to additional system elements of the host, such that the host processor controls the operation of the host by executing instructions that may be stored within the host or external to the host.

As discussed above, data may be written to and read from the memory device 10, for example, by the host whereby the memory device 10 operates as volatile memory, such as Double Data Rate DRAM (e.g., DDR5 SDRAM). The host may, in some embodiments, also include separate non-volatile memory, such as read-only memory (ROM), PC-RAM, silicon-oxide-nitride-oxide-silicon (SONOS) memory, metal-oxide-nitride-oxide-silicon (MONOS) memory, polysilicon floating gate based memory, and/or other types of flash memory of various architectures (e.g., NAND memory, NOR memory, etc.) as well as other types of memory devices (e.g., storage), such as solid state drives (SSD's), MultimediaMediaCards (MMC's), SecureDigital (SD) cards, CompactFlash (CF) cards, or any other suitable device. Further, it should be appreciated that the host may include one or more external interfaces, such as Universal Serial Bus (USB), Peripheral Component Interconnect (PCI), PCI Express (PCI-E), Small Computer System Interface (SCSI), IEEE 1394 (Firewire), or any other suitable interface as well as one or more input devices to allow a user to input data into the host, for example, buttons, switching elements, a keyboard, a light pen, a stylus, a mouse, and/or a voice recognition system, for instance. The host may optionally also include an output device, such as a display coupled to the processor and a network interface device, such as a Network Interface Card (NIC), for interfacing with a network, such as the Internet. As will be appreciated, the host may include many other components, depending on the application of the host.

The host may operate to transfer data to the memory device 10 for storage and may read data from the memory device 10 to perform various operations at the host. Accordingly, to facilitate these data transmissions, in some embodiments, the I/O interface 16 may include a data transceiver 48 that operates to receive and transmit DQ signals to and from the I/O interface 16.

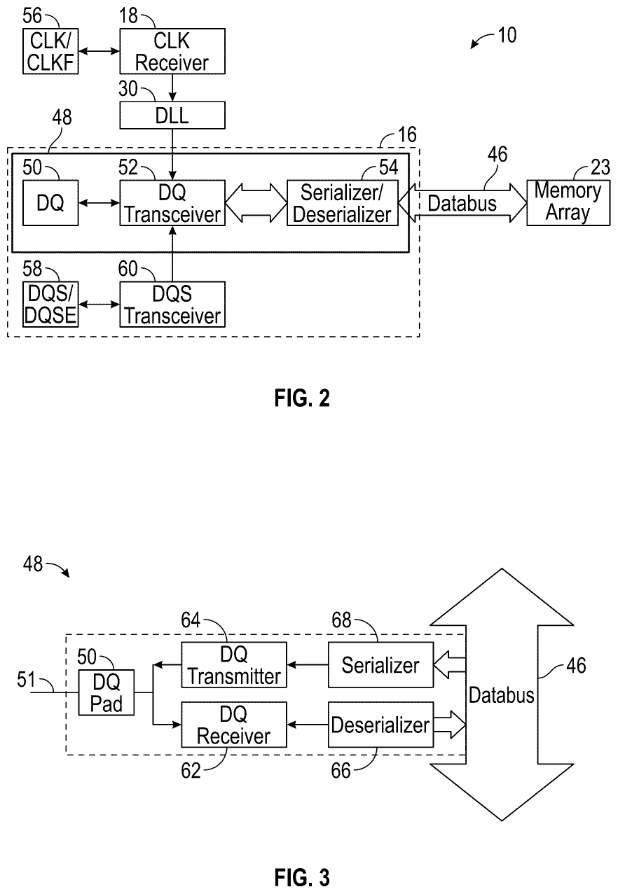

FIG. 2 illustrates the I/O interface 16 of the memory device 10 generally and, more specifically, the data transceiver 48. As illustrated, the data transceiver 48 of the I/O interface 16 may include a DQ connector 50, a DQ transceiver 52, and a serializer/deserializer 54. It should be noted that in some embodiments, multiple data transceivers 48 may be utilized whereby each single data transceiver 48 may be utilized in connection with a respective one of each of upper and lower I/O signals (e.g., DQ<15:8> and DQ<7:0>) corresponding to upper and lower bytes of the data signals, for instance. Thus, the I/O interface 16 may include a plurality of data transceivers 48, each corresponding to one or more I/O signals (e.g., inclusive of a respective DQ connector 50, DQ transceiver 52, and serializer/deserializer 54).

The DQ connector 50 may be, for example a pin, pad, combination thereof, or another type of interface that operates to receive DQ signals, for example, for transmission of data to the memory array 23 as part of a data write operation. Additionally, the DQ connector 50 may operate to transmit DQ signals from the memory device 10, for example, to transmit data from the memory array 23 as part of a data read operation. To facilitate these data reads/writes, a DQ transceiver 52 is present in data transceiver 48. In some embodiments, for example, the DQ transceiver 52 may receive a clock signal generated by the internal clock generator 30 as a timing signal for determining an output timing of a data read operation from the memory array 23. The clock signal transmitted by the internal clock generator 30 may be based upon one or more clocking signals received by the memory device 10 at clock connector 56 (e.g., a pin, pad, the combination thereof, etc.) and routed to the internal clock generator 30 via the clock input circuit 18. Thus, the DQ transceiver 52 may receive a clock signal generated by the internal clock generator 30 as a timing signal for determining an output timing of a data read operation from the memory array 23.

The DQ transceiver 52 of FIG. 2 may also, for example, receive one or more DQS signals to operate in a strobe data mode as part of a data write operation. The signals may be received at a DQS connector 58 (e.g., a pin, pad, the combination thereof, etc.) and routed to the DQ transceiver 52 via a DQS transceiver 60 that operates to control a data strobe mode via selective transmission of the DQS signals to the DQ transceiver 52. Thus, the DQ transceiver 52 may receive DQS signals to control a data write operation from the memory array 23.

As noted above, the data transceiver 48 may operate in modes to facilitate the transfers of the data to and from the memory device 10 (e.g., to and from the memory array 23). For example, to allow for higher data rates within the memory device 10, a data strobe mode in which DQS signals are utilized, may occur. The DQS signals may be driven by an external processor or controller sending the data (e.g., for a write command) as received by the DQS connector 58 (e.g., a pin, pad, the combination thereof, etc.). In some embodiments, the DQS signals are used as clock signals to capture the corresponding input data.

In addition, as illustrated in FIG. 2, the data transceiver 48 also includes a serializer/deserializer 54 that operates to translate serial data bits (e.g., a serial bit stream) into parallel data bits (e.g., a parallel bit stream) for transmission along data bus 46 during data write operations of the memory device 10. Likewise, the serializer/deserializer 54 operates to translate parallel data bits (e.g., a parallel bit stream) into serial data bits (e.g., a serial bit stream) during read operations of the memory device 10. In this manner, the serializer/deserializer 54 operates to translate data received from, for example, a host device having a serial format into a parallel format suitable for storage in the memory array 23. Likewise, the serializer/deserializer 54 operates to translate data received from, for example, the memory array 23 having a parallel format into a serial format suitable for transmission to a host device.

FIG. 3 illustrates the data transceiver 48 as including the DQ connector 50 coupled to data transfer bus 51, a DQ receiver 62, a DQ transmitter 64 (which in combination with the DQ receiver 62 forms the DQ transceiver 52), a deserializer 66, and a serializer 68 (which in combination with the deserializer 66 forms the serializer/deserializer 54). In operation, the host (e.g., a host processor or other memory device described above) may operate to transmit data in a serial form across data transfer bus 51 to the data transceiver 48 as part of a data write operation to the memory device 10. This data is received at the DQ connector 50 and transmitted to the DQ receiver 62. The DQ receiver 62, for example, may perform one or more operations on the data (e.g., amplification, driving of the data signals, etc.) and/or may operate as a latch for the data until reception of a respective DQS signal that operates to coordinate (e.g., control) the transmission of the data to the deserializer 66. As part of a data write operation, the deserializer 66 may operate to convert (e.g., translate) data from a format (e.g., a serial form) in which it is transmitted along data transfer bus 51 into a format (e.g., a parallel form) used for transmission of the data to the memory array 23 for storage therein.

Likewise, during a read operation (e.g., reading data from the memory array 23 and transmitting the read data to the host via the data transfer bus 51), the serializer 68 may receive data read from the memory array 23 in one format (e.g., a parallel form) used by the memory array 23 and may convert (e.g., translate) the received data into a second format (e.g., a serial form) so that the data may be compatible with one or more of the data transfer bus 51 and/or the host. The converted data may be transmitted from the serializer 68 to the DQ transmitter 64, whereby one or more operations on the data (e.g., de-amplification, driving of the data signals, etc.) may occur. Additionally, the DQ transmitter 64 may operate as a latch for the received data until reception of a respective clock signal, for example, from the internal clock generator 30, that operates to coordinate (e.g., control) the transmission of the data to the DQ connector 50 for transmission along the data transfer bus 51 to one or more components of the host.

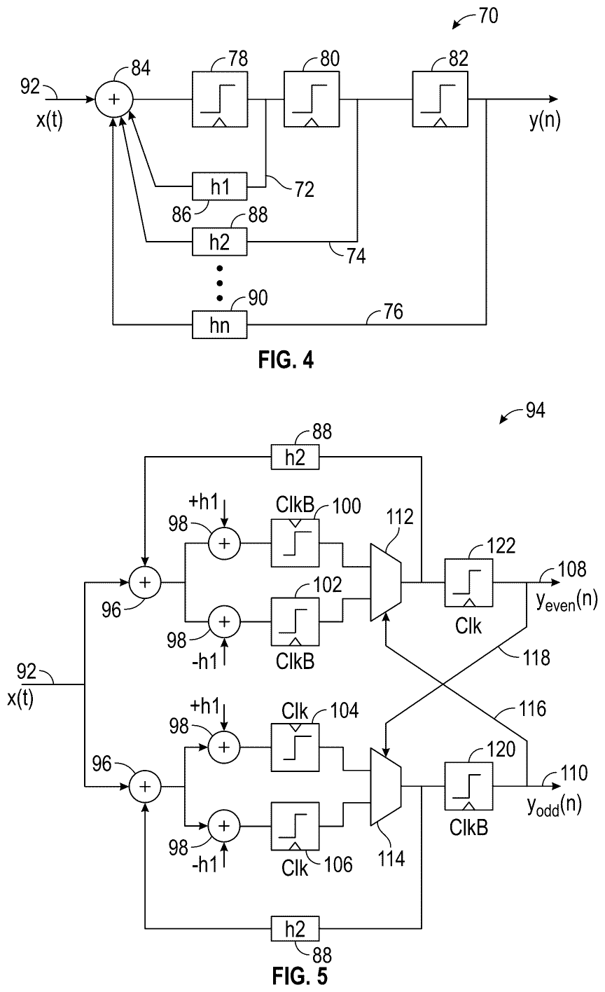

In some embodiments, the data received at the DQ connector 50 may be distorted. For example, data received at the DQ connector 50 may be affected by inter-symbol interference (ISI) in which previously received data interferes with subsequently received data. For example, due to increased data volume being transmitted across the data transfer bus 51 to the DQ connector 50, the data received at the DQ connector 50 may be distorted relative to the data transmitted by the host. One technique to mitigate (e.g., offset or cancel) this distortion and to effectively reverse the effects of ISI is to apply an equalization operation to the data. FIG. 4 illustrates an embodiment of an equalizer that may be used in this equalization operation.

FIG. 4 illustrates one embodiment an equalizer, in particular, a decision feedback equalizer (DFE) 70. As illustrated, the DFE 70 represents an N-tap DFE 70, where “N” is a positive integer value. For example, a 1-tap DFE, a 2-tap DFE, a 3-tap DFE, a 4 tap DFE or another N-tap DFE may be implemented as the DFE 70. The DFE 70 may be disposed separate from or internal to the deserializer 66 or the DQ receiver 62 of FIG. 3. In operation, a binary output (e.g., from a latch or decision-making slicer) is captured in one or more data latches or data registers. In the present embodiment, these data latches or data registers may be disposed in the deserializer 66 and the values stored therein may be latched or transmitted along paths 72, 74, and 76.

When a data bit is received at the DQ receiver 62, it may be identified as being transmitted from the host as bit “x(t)” and may be received at a time to as distorted bit x (e.g., bit x having been distorted by ISI). The most recent bit received prior to distorted bit x being received at the DQ receiver 62, e.g., received at time of t₋₁ that immediately precedes time of t₀, may be identified as x-1 and is illustrated as being transmitted from a data latch 78 along path 72. The second most recent bit received prior to distorted bit x being received at the DQ receiver 62, e.g., received at time of t₋₂ that immediately precedes time of t₋₁, may be identified as x-2 and is illustrated as being transmitted from data latch 80 along path 74. This process can continue with additional latches until latch 82, which corresponds to the Nth latch and transmits the least recent bit (x-N) received prior to distorted bit x being received at the DQ receiver 62, e.g., received at time of t_{-N} that immediately precedes time of t_{-N-1}, which is transmitted along path 76. Bits x-1, x-2, . . . x-N may be considered the group of bits that interfere with received distorted bit x (e.g., bits x-1, x-2, . . . x-N cause ISI to host transmitted bit x) and the DFE 70 may operate to offset the distortion caused by the group of bits x-1, x-2, . . . x-N on host transmitted bit x.

Thus, the values latched or transmitted along paths 72, 74, and 76, may correspond, respectively, to the most recent previous data values (e.g., preceding bits x-1, x-2, . . . x-N) transmitted from the DQ receiver 62 to be stored in memory array 23. These previously transmitted bits are fed back along paths 72, 74, and 76 and are used in generation of weighted tap 86 (e.g., h1), weighted tap 88 (e.g., h2), and weighted tap 90 (e.g., hn) represented as being disposed along paths 72, 74, and 76. Weighted tap 86, weighted tap 88, and weighted tap 90 can each correspond to respective adjustments (e.g., voltages) that may be and added to the received input signal (e.g., data received from the DQ connector 50, such as distorted bit x) by means of the summer 84 (e.g., a summing amplifier). In other embodiments, weighted tap 86, weighted tap 88, and weighted tap 90 may be combined with an initial reference value to generate an offset that corresponds to or mitigates the distortion of the received data (e.g., mitigates the distortion of distorted bit x). In some embodiments, taps are weighted to reflect that the most recent previously received data (e.g., bit x-1 and weighted tap 86) may have a stronger influence on the distortion of the received data (e.g., distorted bit x) than bits received at earlier times (e.g., bits x-2 and x-N). The DFE 70 may operate to generate magnitudes and polarities for weighted tap 86, weighted tap 88, and weighted tap 90 due to each previous bit to collectively offset the distortion caused by those previously received bits.

For example, for the present embodiment, each of previously received bits x-1, x-2, x-3, and x-4 (as bit x-N) could have had one of two values (e.g., a binary 0 or 1), which was transmitted to the deserializer 66 for transmission to the memory array 23 and, additionally, latched or saved in a register for subsequent transmission along respective paths 72, 74, 76, and an additional path corresponding to previously received bit x-3. In this example, sixteen (e.g., 24) possible binary combinations (e.g., 0000, 0001, 0010, . . . , 1110, or 1111) for the group of bits x-1, x-2, x-3, and x-4 would be possible. The DFE 70 operates to select and/or generate corresponding tap values for whichever of the aforementioned sixteen combinations are determined to be present (e.g., based on the received values along paths 72, 74, 76, and the additional path corresponding to previously received bit x-3) to be used to adjust either the input value received from the DQ connector 50 (e.g., distorted bit x) or to modify a reference value that is subsequently applied to the input value received from the DQ connector 50 (e.g., distorted bit x) so as to cancel the ISI distortion from the previous bits in the data stream (e.g., the group of bits x-1, x-2, x-3, and x-4).

Use of distortion correction (e.g., a DFE 70) may be beneficial such that data transmitted from the DQ connector 50 is correctly represented in the memory array 23 without distortion. As noted above, distortion correction circuitry (e.g., equalizer) may be included as part of the DQ receiver 62 but may not be required to be physically located there (e.g., it may instead be coupled to the DQ receiver 62). In some embodiments, the distortion correction circuitry may be operated to provide previously transmitted bit data to correct a distorted bit 81 (e.g., bit having been distorted by ISI and/or system distortions) transmitted via a channel 92 (e.g., connection, transmission line, and/or conductive material).

FIG. 5 illustrates a DFE 94 as an embodiment of an equalizer discussed above. DFE 94 represents a half rate DFE receiver where data (from channel 92) is received at both edges of a clock signal at a frequency of half of the data rate transmitted along channel 92. As illustrated, the DFE 94 represents a 2-tap DFE. However, other variations are contemplated, for example, a 1-tap DFE, a 3-tap DFE, a 4-tap DFE or another N-tap DFE may be implemented as the DFE 94. The DFE 94 may be disposed separate from or internal to the deserializer 66 or the DQ receiver 62 of FIG. 3.

The DFE 94 includes a first stage of summers 96 that each receive a second weighted tap (e.g., h2) as a feedback signal. Additionally, the first stage of summers 96 receive the data stream along channel 92 (e.g., bits x, x-1, x-2, etc.). Additionally, the DFE 94 is a speculative equalizer. Accordingly, a first weighted tap (e.g., h1) is transmitted as an input to a second stage of summers 98. As illustrated, the first weighted tap is implemented via speculation, so a positive weighted tap value (e.g., +h1) and a negative weighted tap value (e.g., −h1) are provided to the second stage of summers 98.

The DFE 94 further includes latch 100, latch 102, latch 104, and latch 106 (e.g., data slicers). These latches 100, 102, 104, and 106 are controlled by a clock signal CLK. CLK may be a half-rate clock signal, whereby latches 100 and 102 sample data on a rising edge of CLK to generate even data bits, which are output from the DFE 94 along path 108. Likewise, latches 104 and 106 sample data on a falling edge of CLK to generate odd data bits, which are output from the DFE 94 along path 110. The sampled data from latch 100 and latch 102 is transmitted to a selection circuit 112 while the sampled data from latch 104 and latch 106 is transmitted to a selection circuit 114. Selection circuit 112 and selection circuit 114 can be 2-to-1 multiplexers.

Selection circuit 112, as illustrated, is controlled by a feedback signal transmitted along path 116 and selection circuit 114 is controlled by a feedback signal transmitted along path 118. In operation, the feedback signal along path 116 operates to select the correct weighed tap value (e.g., +h1 or −h1) to be applied by selecting the respective input to the selection circuit 112 that corresponds to that correct weighted tap value as the signal output from the selection circuit 112. Similarly, the feedback signal along path 118 operates to select the correct weighed tap value (e.g., +h1 or −h1) to be applied by selecting the respective input to the selection circuit 112 that corresponds to that correct weighted tap value as the signal output from the selection circuit 114. Furthermore, as illustrated, the feedback signal along path 116 provides the selection signal to an even bit portion of the DFE 94 (i.e., the upper illustrated portion of the DFE 94), since any previous bit was decided by the odd portion of the DFE 94, inclusive of latch 120) and the feedback signal along path 118 provides the selection signal to an odd bit portion of the DFE 94 (i.e., the lower illustrated portion of the DFE 94), since any previous bit was decided by the even portion of the DFE 94 inclusive of latch 122.

In operation, the tap signal path of Tap1 (i.e., providing hl to the second stage of summers 98) is t_{clk-to-Q}+tu, where t_{clk-to-Q} is the clock-to-Q delay of the respective latches 100, 102, 104, or 106 for a given (e.g., selected) path and tu is the propagation delay of the respective selection circuit 112, 114 for the given (e.g., selected) path. However, the tap signal path of Tap2 (i.e., providing h2 to the first stage of summers 96) is greater than the tap signal path of Tap1. The tap signal path of Tap2 is t_{clk-to-Q}+tu+ts, where t_{clk-to-Q} is the clock-to-Q delay of the respective latches 100, 102, 104, or 106 for a given (e.g., selected) path, tu is the propagation delay of the respective selection circuit 112, 114 for the given (e.g., selected) path, and ts is the settling time attributable to the first stage of summers 96.

As operating speeds increase, the propagation delays described above, particularly with respect to, for example, tap signal path of Tap1 and Tap2, can affect the operation of the DFE 94. This can be due to the propagation delay (e.g., tu) of the respective selection circuit 112, 114 for the given (e.g., selected) path. Indeed, as operating speeds increase, the tap signal path of Tap 1 (i.e., providing h1 to the second stage of summers 98) or Tap2 (i.e., providing h2 to the first stage of summers 96), for example, can arrive subsequent to the data being provided from channel 92 due primarily to the propagation delay (e.g., tu) of the respective selection circuit 112, 114 for the given (e.g., selected) path. Therefore, the weighting value associated with one or both of h1 and h2 will not be correctly applied to the data (i.e., bit) being transmitted to the first stage of summers 96 and/or the second stage of summers 98.

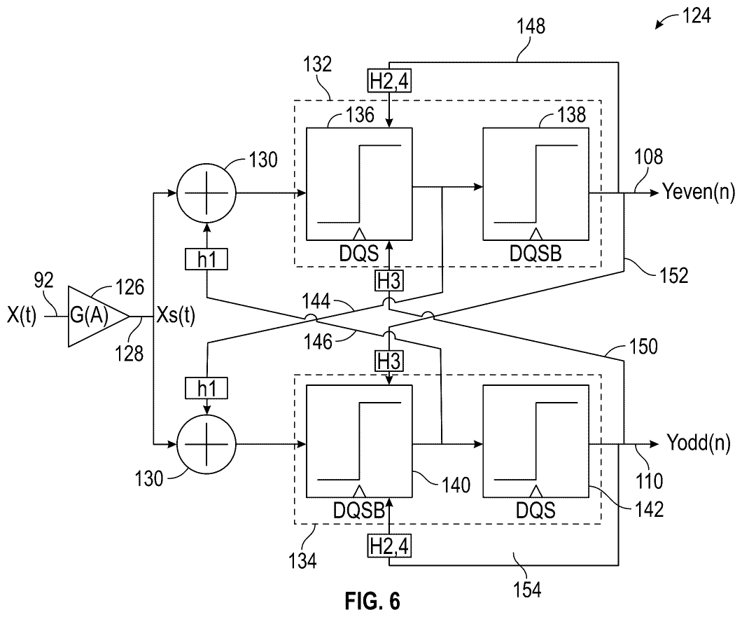

FIG. 6 illustrates DFE 124 as an embodiment of an equalizer discussed above that can overcome the delay issues associated with the propagation delay (e.g., tu) of the respective selection circuit 112, 114 for the given (e.g., selected) path in DFE 94. DFE 124 represents a half rate unroll (no mux) DFE receiver where data (from channel 92) is received at both edges of a clock signal at a frequency of half of the data rate transmitted along channel 92. However, there is no unroll MUX delay (i.e., tu propagation delay) such as that associated with DFE 94 of FIG. 5. As illustrated, the DFE 124 represents a 4-tap DFE. However, other variations are contemplated, for example, a 1-tap DFE, a 2-tap DFE, a 3-tap DFE or another N-tap DFE may be implemented as the DFE 124. The DFE 124 may be disposed separate from or internal to the deserializer 66 or the DQ receiver 62 of FIG. 3.

Distorted bit(s) may be transmitted to an amplifying device 126 from a channel 92 and transmitted from the amplifying device 126 to the DFE 124. The amplifying device 126 may be, for example, a variable gain amplifier. In some embodiments, the amplifying device may be a two stage amplifier with Continuous Time Linear Equalization (CTLE) in one of the stages of the amplifier. The distorted bit may be transmitted simultaneously with a DQ reference signal having a predetermined voltage (VRDQ) to the DFE 124. VRDQ may represent a threshold value (e.g., a voltage level) for determination if the transmitted bit received by the DQ connector 50 was a logical low (e.g., 0) or a logical high (e.g., 1). Thus, data bits may be received at a first input of the amplifying device 126 and a reference signal (e.g., VRDQ) may be received at a second input of the amplifying device 126.

In some embodiments, as noted above, the amplifying device 126 of FIG. 6 may represent a variable gain amplifier and continuous-time linear equalizer (CTLE). The output of the variable gain amplifier (e.g., Xs(t)) may be set to predetermined levels (e.g., settings), for example, values approximately between 0.5 times and 2.0 times the DC reference signal input to the variable gain amplifier or another level. The CTLE may operate to, for example, mitigate inter-symbol interference (ISI). More particularly, the CTLE generally operates to offset losses in the data stream (leading to a distorted bit) caused by, for example, the channel 92. The CTLE can generally operate to amplify higher frequency content of the data stream to equalize for these effects to the data stream (i.e., to boost higher frequency content, therefore making it effectively equivalent to amplitude at lower frequency components of the data stream). Accordingly, use of a CTLE in addition to a variable gain amplifier can operate to provide more reliable signals to the DFE 124 (e.g., increase the reliability of one or more of the distorted bit).

In some embodiments, the CTLE can be integrated into the amplifying device 126 (e.g., a portion of one of the stages of a variable gain amplifier). However, it should be noted that the CTLE circuitry can instead, for example, be disposed separately from (i.e., in series with) a variable gain amplifier used in the amplifying device. As illustrated, the amplifying device 126 receives data bits along channel 92, as well a reference signal, VRDQ (e.g., the DQ reference signal or “Vref”) and transmits an amplified result along path 128 to summers 130.

In the illustrated example, the DFE 124 may be operated to correct the distortion from the distorted bit (e.g., bit x) using the tap weighted with previous bit data. Data (e.g., logical 1 or logical 0) for a given bit may be passed through the amplifying device and may be transmitted through the path 128 to summers 130. The magnitudes and polarities of a weighted tap 86 (e.g., h1) may offset the total distortion caused by the x-1 bit via summers 130, which can operate as current summers that apply current to the distorted bit x to offset for distortion caused by the x−1 bit. The resultant signals output from the summers 130 are transmitted to a double tail latch 132 in an even bit portion of the DFE 124 (i.e., the upper illustrated portion of the DFE 124) and a double tail latch 134 in an odd bit portion of the DFE 124 (i.e., the lower illustrated portion of the DFE 94). The double tail latch 132 can include latch 136 and latch 138 while the double tail latch 134 can include latch 140 and latch 142. In operation latch 136 and latch 138 may operate in a manner similar to, for example, latch 100 and 122 and latch 140 and latch 142 may operate in a manner similar to, for example, latch 104 and 120. However, as illustrated, there is no selection circuit 112 or selection circuit 114 and, accordingly, no corresponding tu as propagation delay in the DFE 124. This can save approximately, for example, 60 psec, 70 70 psec, 80 psec, 90 psec, 100 psec or another amount of time with respect to the looptime margin of DFE 124 with respect to the looptime margin of DFE 94.

Path 144 operates as a feedback path transmitting a first weighted tap (h1) from an output of latch 136 to the summer 130 disposed in the odd bit portion of the DFE 124. Similarly, path 146 operates as a feedback path transmitting the first weighted tap (h1) from an output of latch 140 to the summer 130 disposed in the even bit portion of the DFE 124. Additionally, as illustrated, the timing of the output of latch 136 is controlled by the DQS signal while the timing of the output of latch 138 is controlled by the inverse of the DQS signal, DQSB. The timing of the output of latch 140 is controlled by DQSB and the timing of the output of latch 142 is controlled by DQS. The signal generated by latch 136 is based upon the output from the summer 130 disposed in the even bit portion of the DFE 124, as adjusted by a second weighted tap (h2) received from the output of latch 138 along path 148, a fourth weighted tap (h4) received from the output of latch 138 along path 148, and a third weighted tap (h3) received from the output of latch 142 along path 150. As noted above, the output of latch 136 is the resultant signal modified by the aforementioned weighted taps (h2, h3, and h4) and is transmitted along path 144, where it is used in the generation of the first weighted tap (h1) transmitted to the summer 130 disposed in the odd bit portion of the DFE 124. Additionally, the output of latch 136 is transmitted to latch 138 as an input signal to latch 138.

Latch 138 generates an output as controlled by the DSQB signal and this output is transmitted as the second weighted tap (h2) or the fourth weighted tap (h4) along path 148 to latch 136 or is transmitted as a third weighted tap (h3) to latch 140, depending on the state of operation of the double tail latch 132. For example, whether the output is transmitted as the second weighted tap (h2), the fourth weighted tap (h4) along path 148 to latch 136, or is transmitted as a third weighted tap (h3) to latch 140 depends on the phase of the DQSB signal (e.g., 0°, 90°, 180°, or 270°) that is being applied as a control signal for the latch 138. The output of latch 138 is also transmitted as the even data bits, which are output from the DFE 124 along path 108.

As additionally illustrated, the signal generated by latch 140 is based upon the output from the summer 130 disposed in the odd bit portion of the DFE 124, as adjusted by a second weighted tap (h2) received from the output of latch 142 along path 154, a fourth weighted tap (h4) received from the output of latch 142 along path 154, and a third weighted tap (h3) received from the output of latch 138 along path 152. As noted above, the output of latch 140 is the resultant signal modified by the aforementioned weighted taps (h2, h3, and h4) and is transmitted along path 146, where it is used in the generation of the first weighted tap (h1) transmitted to the summer 130 disposed in the even bit portion of the DFE 124. Additionally, the output of latch 140 is transmitted to latch 142 as an input signal to latch 138.

Latch 142 generates an output as controlled by the DSQB signal and this output is transmitted as the second weighted tap (h2) or the fourth weighted tap (h4) along path 154 to latch 140 or is transmitted as a third weighted tap (h3) along path 150 to latch 136, depending on the state of operation of the double tail latch 134. For example, whether the output is transmitted as the second weighted tap (h2), the fourth weighted tap (h4) along path 154 to latch 140, or is transmitted as a third weighted tap (h3) to latch 136 depends on the phase of the DQS signal (e.g., 0°, 90°, 180°, or 270°) that is being applied as a control signal for the latch 138. The output of latch 142 is also transmitted as the odd data bits, which are output from the DFE 124 along path 110.

Regarding the first weighted tap (h1) provided to each of the summers 130, it should be noted that the signal transmitted to the summers 130 may be selectively positive (i.e., +h1) or negative (i.e., −h1) as selectable by summers. That is, a first weighted tap can be provided as both a positive weighted tap value (e.g., +h1) and a negative weighted tap value (e.g., −h1). Additionally, in operation, the tap signal path of Tap1 (i.e., providing h1 to the summers 130) is t_{clk-to-Q}+ts, where t_{clk-to-Q} is the clock-to-Q delay of the respective latches 138, 138, 140, or 142 for a given (e.g., selected) path and ts is the settling time attributable to the summers 130. The tap signal path of Tap2 is t_{clk-to-Q}. In this manner, tu (i.e., the propagation delay of any selection circuit) is omitted from the DFE 124 and ts is the settling time attributable to the first stage of summers 96.

Because tu is omitted in the DFE 124, as operating speeds increase, the propagation delays described above with respect to DFE 94 can be avoided. For example, as operating speeds increase, the tap signal path of Tap2 (i.e., providing h2 to the first stage of the double tail latch 132 and the first stage of the double tail latch 134), for example, can arrive before data being provided from channel 92. Therefore, the weighting value associated with h2 will be correctly applied to the data (i.e., bit) being transmitted to the respective latch 136 and latch 140.

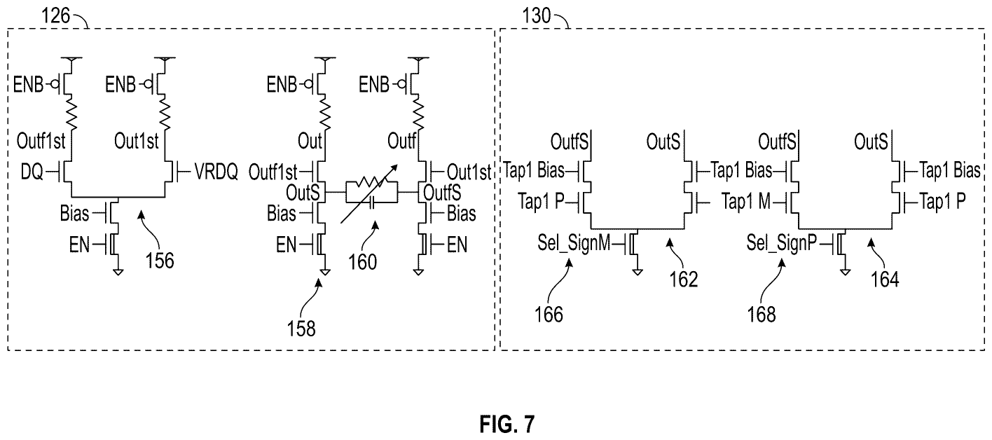

FIG. 7 illustrates an example of a first embodiment of the summer 130 as well as an embodiment of the amplifying device 126 usable in conjunction with a DFE, for example, DFE 124. The amplifying device 126 is a variable gain amplifier (VGA) and the amplifying device 126 is illustrated as a two stage amplifier with a first VGA stage 156 and a second VGA stage 158 having Continuous Time Linear Equalization (CTLE) circuitry 160 therein. As illustrated, the first VGA stage 156 receives both DQ and reference signal VRDQ as gate signals and generates output signals Out1st and Outf1st (the inverted signal of Out1st) as gate signals for the second VGA stage 158. These gate signals (Out1st and Outf1st) are utilized in generation of output signals OutS and OutfS (where OutfS is the inverted output of OutS). OutS and OutfS can be read as signals related to the Out and Outf signals, which themselves can constitute the Xs(t) output from the amplifying device 126 coupled to the DFE 124 of FIG. 6. That is, OutS and OutfS can constitute the Xs(t) output from the amplifying device 126 to the DFE 124 of FIG. 6.

As additionally noted above, FIG. 7 illustrates a summer 130 of the DFE 124. As illustrated, the summer 130 includes a first summing stage 162 and a second summing stage 164 connected to one another in parallel. In operation, the first summing stage 162 and the second summing stage 164 each receive the OutS and OutfS signal from the second VGA stage 158 of amplifying device 126. By using the OutS and OutfS output signals, there is a lessened chance for the summer to impact the Xs(t) signal (e.g., reduced parasitic impact on Xs(t)), since the Out and Outf signals are not used in the summer 130 for tap polarity selection. Additionally, each of the first summing stage 162 and the second summing stage 164 receive a Tap1P and Tap1M signal, which can correspond to the weighted tap value h1 transmitted to the summer 130, for example, as a positive and a negative value. Each of the first summing stage 162 and the second summing stage 164 also receive a Tap1Bias signal that operates to control the range and step of the respective Tap1 or Tap1M of the transistor coupled to the transistor that receives the Tap1Bias signal. Finally, the first summing stage 162 receives a select signal along path 166 (Sel_SignM) that operates to select/output a negative tap value for the h1 tap value applied in the summer 130. Likewise, second summing stage 164 receives a select signal along path 168 (Sel_SignP) that operates to select a positive tap value for the h1 tap value applied in the summer 130. In this manner, the first weighted tap is selectively implemented as a positive weighted tap value (e.g., +h1) or as a negative weighted tap value (e.g., −h1) for application in the summer 130. However, other embodiments for generation of the first weighted tap value can be implemented.

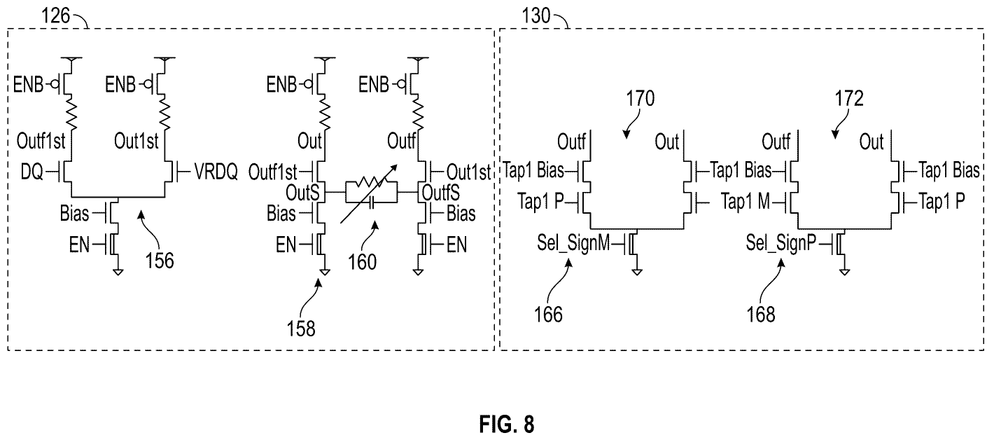

For example, FIG. 8 illustrates an example of a second embodiment of the summer 130 as well as an embodiment of the amplifying device 126 usable in conjunction with a DFE, for example, DFE 124. The amplifying device 126 is a variable gain amplifier (VGA) and the amplifying device 126 is illustrated as a two stage amplifier with a first VGA stage 156 and a second VGA stage 158 having Continuous Time Linear Equalization (CTLE) circuitry 160 therein. As illustrated, the first VGA stage 156 receives both DQ and reference signal VRDQ as gate signals and generates output signals Out1st and Outf1st (the inverted signal of Out1st) as gate signals for the second VGA stage 158. These gate signals (Out1st and Outf1st) are utilized in generation of output signals OutS and OutfS (where OutfS is the inverted output of OutS) and Out and Outf. OutS and OutfS can be read as the Xs(t) output from the amplifying device 126 to the DFE 124 of FIG. 6.

As additionally noted above, FIG. 8 illustrates a summer 130 of the DFE 124. As illustrated, the summer 130 includes a first summing stage 170 and a second summing stage 172 connected to one another in parallel. In operation, the first summing stage 170 and the second summing stage 172 each receive the Out and Outf signal from the second VGA stage 158 of amplifying device 126. Additionally, each of the first summing stage 170 and the second summing stage 172 receive a Tap1P and Tap1M signal, which can correspond to the weighted tap value h1 transmitted to the summer 130, for example, as a positive and a negative value. Each of the first summing stage 170 and the second summing stage 172 also receive a Tap1Bias signal that operates to control the range and step of the respective Tap1 or Tap1M of the transistor coupled to the transistor that receives the Tap1Bias signal. Finally, the first summing stage 170 receives a select signal along path 166 (Sel_SignM) that operates to select/output a negative tap value for the h1 tap value applied in the summer 130. Likewise, second summing stage 172 receives a select signal along path 168 (Sel_SignP) that operates to select a positive tap value for the h1 tap value applied in the summer 130. In this manner, the first weighted tap is selectively implemented as a positive weighted tap value (e.g., +h1) or as a negative weighted tap value (e.g., −h1) for application in the summer 130.

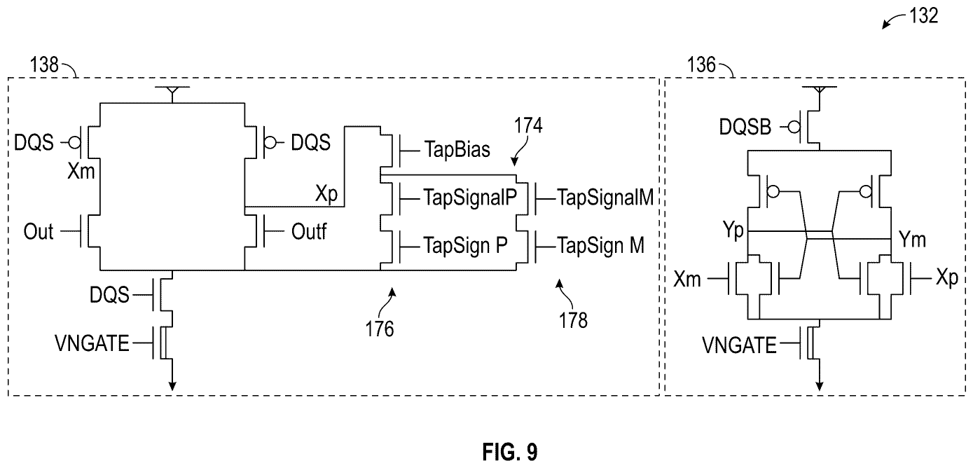

FIG. 9 illustrates an embodiment of the double tail latch 132 of the DFE 124 of FIG. 6. As illustrated, at least a portion of the latch 136 illustrates generation of Yp and Ym, which can represent the nodes from which the Tap1P and Tap1M signals are transmitted to the summer 130 of FIGS. 7 and 8. Likewise, FIG. 9 illustrates at least a portion of the latch 138. For example, DFE stage 174 (e.g., for a Tap2, i.e., h2) is illustrated, whereby the polarity of Tap2 (e.g., h2) is controlled by parallel connections between a positive tap circuit 176 and a negative tap circuit 178. Additionally, each of the positive tap circuit 176 and a negative tap circuit 178 is coupled to a TapBias signal that operates to control the range and step of the respective TapSignalP or TapSignalM (i.e., positive Tap signal and negative tap signal, which can correspond to the weighted tap value h2 transmitted to the summer 130, for example, as a positive and a negative value). The positive tap circuit 176 receives TapSignalP (corresponding to, for example, h2) and the negative tap circuit 178 receives TapSignalM (corresponding to, for example, −h2). The positive tap circuit 176 receives a select signal (TapSignP) that operates to select/output a positive tap value for the h2 tap value. Likewise, the negative tap circuit 178 receives a select signal (TapSignM) that operates to select/output a negative tap value for the h2 tap value (−h2). In this manner, the direction (polarity) of Tap2 (as well as Tap3 and Tap4) for the DFE 124 is controlled by the DFE stage 174.

Through the use of the above noted techniques and systems, minimized unroll (i.e., no multiplexer) decision feedback equalizers may be implemented. The DFE Tap1 feedback can be transmitted from an intermediate node disposed between latches of a double tail latch of the DFE. Additionally, in some embodiments, the Tap1 summer does not increase the parasitic capacitance of Xs(t) within the variable gain amplifier. This can be accomplished, for example, through selection of alternate voltages that relate to Xs(t) but are not the Xs(t) signals themselves. Additional taps, e.g., Tap2, Tap3, Tap4, etc. can be generated without the use of logic gates, such as NAND based multiplexers to assist in the reduced looptime margin of the DFE 124.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. A device, comprising:
an amplifying device that when in operation transmits a series of amplified data signals; and
a decision feedback equalizer (DFE) circuit, DFE circuit comprises:
a first summer circuit coupled to the amplifying device and configured to receive a first amplified data signal of the series of amplified data signals;
a second summer circuit coupled to the amplifying device in parallel with the first summer circuit and configured to receive a second amplified data signal of the series of amplified data signals;
a first double tail latch circuit coupled to the first summer circuit to receive a first output signal generated by the first summer circuit, wherein the first double tail latch circuit comprises a first latch, a second latch, and a first path disposed between the first latch and the second latch;
a second double tail latch circuit coupled to the second summer circuit to receive a second output signal generated by the second summer circuit, wherein the second double tail latch circuit comprises a third latch, a fourth latch, and a second path disposed between the first latch and the second latch;
a first feedback path coupled to the second path and the first summer circuit, wherein the first feedback path transmits a first tap signal to the first summer circuit to adjust the first amplified data signal received by the first summer circuit; and
a second feedback path coupled to a first output of the first double tail latch circuit and the first latch, wherein the second feedback path transmits a second tap signal to the first latch to adjust the first output signal generated by the first summer circuit.

2. The device of claim 1, wherein the amplifying device comprises a variable gain amplifier (VGA) and a continuous-time linear equalizer (CTLE) that operates to mitigate inter-symbol interference (ISI) on a data signal from a received data stream comprising the data signal.

3. The device of claim 2, wherein the CTLE is internal to the VGA.

4. The device of claim 3, wherein the first summer circuit is configured to receive a select signal.

5. The device of claim 4, wherein the first summer circuit is configured to select a positive tap value as a polarity of the first tap signal when the select signal has a first value.

6. The device of claim 5, wherein the first summer circuit is configured to select a negative tap value as the polarity of the first tap signal when the select signal has a second value.

7. The device of claim 1, comprising a third feedback path coupled to the first path and the second summer circuit, wherein the third feedback path transmits a third tap signal to the second summer circuit to adjust the second amplified data signal received by the second summer circuit.

8. The device of claim 7, comprising a fourth feedback path coupled to a second output of the second double tail latch circuit and the third latch, wherein the fourth feedback path transmits a fourth tap signal to the third latch to adjust the second output signal generated by the second summer circuit.

9. The device of claim 8, comprising a fifth feedback path coupled to the first output of the first double tail latch circuit and the third latch, wherein the fifth feedback path transmits a fifth tap signal to the third latch to adjust the second output signal generated by the second summer circuit.

10. The device of claim 9, comprising a sixth feedback path coupled to the second output of the second double tail latch circuit and the first latch, wherein the sixth feedback path transmits a sixth tap signal to the first latch to adjust the first output signal generated by the first summer circuit.

11. The device of claim 8, comprising a third path coupled to the first output of the first double tail latch circuit, wherein the third path is configured to transmit even bits of a DFE adjusted data stream from the DFE circuit.

12. The device of claim 11, comprising a fourth path coupled to the second output of the second double tail latch circuit, wherein the fourth path is configured to transmit odd bits of the DFE adjusted data stream from the DFE circuit.

13. A device, comprising:
an amplifying device comprising:
a first amplifying stage configured to generate a first output signal as a first signal and an inverse of the first output signal as a second signal; and
a second amplifying stage coupled to the first amplifying stage, wherein the second amplifying stage comprises:
a first transistor comprising a first drain, a first gate coupled to the first amplifying stage to receive the first signal, and a first source;
a first path coupled to the first drain, wherein the first path transmits an first amplified data signal from the second amplifying stage of the amplifying device;
a second transistor comprising a second drain, a second gate coupled to the first amplifying stage to receive the second signal, and a second source;
a second path coupled to the second drain, wherein the second path transmits a second amplified data signal as an inverse of the first amplified data signal from the second amplifying stage of the amplifying device;
a third path coupled to the first source, wherein the third path transmits a second output signal related to the first amplified data signal; and
a fourth path coupled to the second source, wherein the fourth path transmits a third output signal related to the second amplified data signal; and
a first summer circuit coupled to the amplifying device, wherein the first summer circuit comprises:
a first summing circuit stage and a second summing circuit stage coupled in parallel, wherein the first summing circuit stage comprises:
a first input coupled to the fourth path to receive the third output signal;
a third transistor coupled to the first input, wherein the third transistor comprises a third gate configured to receive a tap signal having a positive tap value;
a second input coupled to the third path to receive the second output signal;
a fourth transistor coupled to the second input, wherein the fourth transistor comprises a fourth gate configured to receive an inverse tap signal having a negative tap value; and
a fifth transistor coupled to the third transistor and the fourth transistor and comprising a fifth gate coupled to a third input of the first summing circuit to receive a first select signal, wherein the first summing circuit transmits an output tap signal having a polarity in common with the negative tap value based upon the first select signal.

14. The device of claim 13, wherein the second summing circuit stage comprises:
a fourth input coupled to the fourth path to receive the third output signal;
a sixth transistor coupled to the fourth input, wherein the sixth transistor comprises a sixth gate configured to receive the inverse tap signal having the negative tap value;
a fifth input coupled to the third path to receive the second output signal;
a seventh transistor coupled to the fifth input, wherein the seventh transistor comprises a seventh gate configured to receive the tap signal having the positive tap value; and
an eighth transistor coupled to the sixth transistor and the seventh transistor and comprising an eighth gate coupled to a sixth input of the second summing circuit to receive a second select signal, wherein the second summing circuit transmits a second output tap signal having a second polarity in common with the positive tap value based upon the second select signal.

15. The device of claim 14, comprising a first double tail latch circuit coupled to a second summer circuit disposed in parallel with the first summer circuit, wherein the first double tail latch circuit comprises a first latch, a second latch, and a node disposed along a fifth path coupling the first latch and the second latch.

16. The device of claim 15, comprising a sixth path coupled to the node and at least one of the third gate, the fourth gate, the seventh gate, or the eighth gate.

17. A device, comprising:
an amplifying device comprising:
a first transistor comprising a first drain, a first gate, and a first source;
a first path coupled to the first drain, wherein the first path transmits an first amplified data signal;
a second transistor comprising a second drain, a second gate, and a second source; and
a second path coupled to the second drain, wherein the second path transmits a second amplified data signal as an inverse of the first amplified data signal; and
a summer circuit coupled to the amplifying device, wherein the summer circuit comprises:
a first input coupled to the second path to receive the second amplified data signal;
a third transistor coupled to the first input, wherein the third transistor comprises a third gate configured to receive a tap signal having a positive tap value;
a second input coupled to the first path to receive the first amplified data signal;
a fourth transistor coupled to the second input, wherein the fourth transistor comprises a fourth gate configured to receive an inverse tap signal having a negative tap value; and
a fifth transistor coupled to the third transistor and the fourth transistor and comprising a fifth gate coupled to a third input of the summer circuit to receive a first select signal, wherein the summer circuit transmits an output tap signal having a polarity in common with the negative tap value based upon the first select signal.

18. The device of claim 17, comprising a continuous-time linear equalizer (CTLE) circuit coupled to the first source and the second source.

19. The device of claim 17, comprising a double tail latch circuit coupled to the summer circuit, wherein the double tail latch circuit comprises a first latch, a second latch, and a node disposed along a third path coupling the first latch and the second latch.

20. The device of claim 19, comprising a fourth path coupled to the node and the summer circuit to provide a weighted tap value to the summer circuit.
